(19) United States
(12) Patent Application Publication
(10) Pub. No.: US 2024/0339349 A1
(43) Pub. Date: Oct. 10, 2024

(54) ADVANCED METHOD FOR CREATING ELECTROSTATIC CHUCK (ESC) MESA PATTERNS

(71) Applicant: Applied Materials, Inc., Santa Clara, CA (US)

(72) Inventors: Joseph Sommers, Roseville, CA (US); Joseph Behnke, San Jose, CA (US); Alexander Sulyman, San Francisco, CA (US); Jaeyong Cho, Mesa, AZ (US)

(21) Appl. No.: 18/131,534

(22) Filed: Apr. 6, 2023

(51) Int. Cl. H01L 21/683; H01L 21/67; H01L 21/673

(52) U.S. Cl. CPC H01L 21/6833; H01L 21/67115; H01L 21/67323

(57) ABSTRACT

Embodiments disclosed herein include an electrostatic chuck (ESC). In an embodiment, the ESC comprises a substrate with a first surface, where the first surface has a first surface roughness. The ESC may further comprise a plurality of mesas extending up from the first surface. In an embodiment, the plurality of mesas each include a second surface, where the second surface has a second surface roughness. In an embodiment the first surface roughness and the second surface roughness both have an average surface roughness Ra of approximately 0.3 μm or lower.

### BACKGROUND

### 1) Field

Embodiments relate to the field of semiconductor manufacturing and, in particular, a laser ablation process for fabricating electrostatic chucks (ESCs) with customizable mesa and gas groove patterns.

### 2) Description of Related Art

In semiconductor processing, chucks, such as electrostatic chucks (ESCs) are used in order to secure wafers or other substrates during different processing operations. An ESC device may induce an electrostatic clamping force that holds the wafer against the ESC. ESC devices may include Coulomb chucks or Johnsen-Rahbek (JR) chucks. Generally, a dielectric surface (typically a ceramic) is the substrate that interfaces with the wafer. As semiconductor processing has become more complex, the ESC has also increased in complexity. Often, the ceramic surface of the ESC is patterned in order to form features, such as mesas (or protrusions) as well as grooves or channels for flowing backside gasses.

Currently, the patterning process of the ceramic substrate is implemented with mechanical removal processes. For example, masking, machining, grinding, and material blasting with abrasives are some processing operations that need to be implemented for the fabrication of an ESC. These processes are time consuming. Additionally, extensive cleaning to remove any residual particles that could cause contamination is needed. Further, such processing operations may result in a high surface roughness. Dimensional control of such processes is also limited. For example, typical tolerances for machined features on the ESC are around 125 μm or greater. Existing processing operations also limit flexibility in process design. Due to the complex nature of the fabrication, design changes (whether small or large scale) may require an entirely new process flow.

### SUMMARY

Embodiments disclosed herein include an electrostatic chuck (ESC). In an embodiment, the ESC comprises a substrate with a first surface, where the first surface has a first surface roughness. The ESC may further comprise a plurality of mesas extending up from the first surface. In an embodiment, the plurality of mesas each include a second surface, where the second surface has a second surface roughness. In an embodiment, the first surface roughness and the second surface roughness both have an average surface roughness Ra of approximately 0.3 μm or lower.

Embodiments disclosed herein may also include electrostatic chuck that comprises a substrate with a center and an edge. In an embodiment, a first mesa is proximate the center of the substrate, where the first mesa has a first shape and a first height. In an embodiment, a second mesa is proximate the edge of the substrate, where the second mesa has a second shape and a second height. In an embodiment, the first shape is different than the second shape and/or the first height is different than the second height.

Embodiments disclosed herein further comprise a method of forming an electrostatic chuck. In an embodiment, the method comprises polishing a first surface of a substrate, and forming a plurality of mesas into the first surface of the substrate with a laser ablation process. In an embodiment, the method may further comprise forming a gas groove into the substrate between mesas.

### BRIEF DESCRIPTION OF THE DRAWINGS

FIG. 1A is a plan view illustration of an electrostatic chuck (ESC) with mesas extending up from a ceramic substrate.

FIG. 1B is a cross-sectional illustration of the ESC in FIG. 1A along line B-B′.

FIG. 1C is a zoomed in illustration of the ESC that illustrates the high surface roughness of patterned surfaces that are generated using conventional fabrication processes.

FIG. 2 is a process flow diagram of a process for fabricating an ESC with a laser ablation process, in accordance with an embodiment.

FIG. 3A is a cross-sectional illustration of a polished ESC substrate, in accordance with an embodiment.

FIG. 3B is a cross-sectional illustration of the ESC during a laser ablation process to form the mesas, in accordance with an embodiment.

FIG. 3C is a cross-sectional illustration of the ESC during a laser ablation process to form gas grooves, in accordance with an embodiment.

FIG. 4A is a cross-sectional illustration of an ESC with uniform mesas, in accordance with an embodiment.

FIG. 4B is a cross-sectional illustration of an ESC with mesas that are taller at a center of the ESC compared to an edge of the ESC, in accordance with an embodiment.

FIG. 4C is a cross-sectional illustration of an ESC with mesas that are shorter at a center of the ESC compared to an edge of the ESC, in accordance with an embodiment.

FIG. 5 is a zoomed in cross-sectional illustration of an ESC that shows the uniform surface roughness between the top surface of the mesas and the recessed surface of the substrate, in accordance with an embodiment.

FIG. 6A is a zoomed in cross-sectional illustration of an ESC with mesas that include domed top surfaces and vertical sidewalls, in accordance with an embodiment.

FIG. 6B is a zoomed in cross-sectional illustration of an ESC with domed mesas, in accordance with an embodiment.

FIG. 6C is a zoomed in cross-sectional illustration of an ESC with mesas with different shapes, in accordance with an embodiment.

FIG. 6D is a zoomed in cross-sectional illustration of an ESC with mesas and a gas groove between mesas, in accordance with an embodiment.

FIG. 6E is a zoomed in cross-sectional illustration of an ESC with mesas and a gas groove that have rounded corners, in accordance with an embodiment.

FIG. 7 is a plan view illustration of an ESC with mesas and gas grooves, in accordance with an embodiment.

FIG. 8 is a plan view illustration of an ESC with mesas that have non-uniform dimensions from center to edge, in accordance with an embodiment.

FIG. 9 illustrates a block diagram of an exemplary computer system that may be used in conjunction with a processing tool, in accordance with an embodiment.

### DETAILED DESCRIPTION

Systems described herein include a laser ablation process for fabricating electrostatic chucks (ESCs) with customizable mesa and gas groove patterns. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

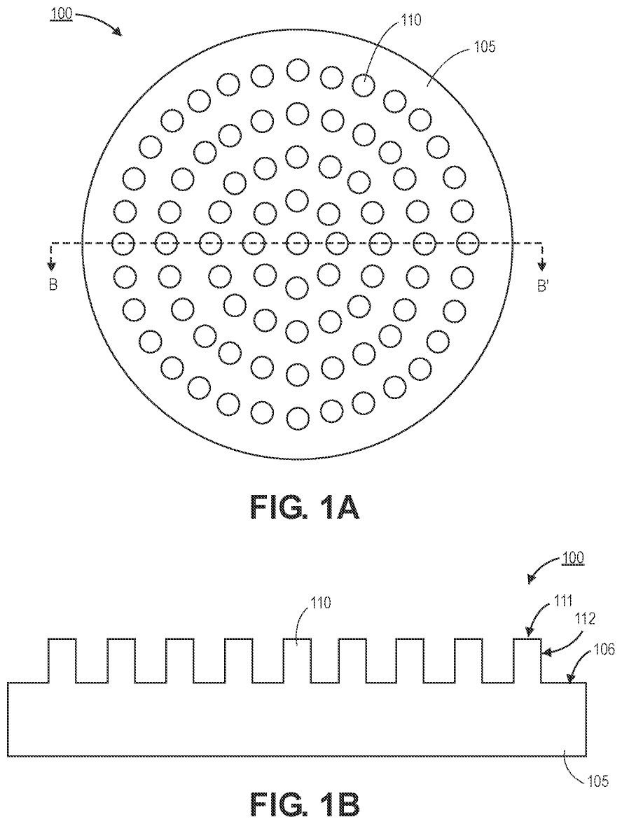

To provide context for embodiments disclosed herein, a typical electrostatic chuck (ESC) 100 is shown in FIG. 1A. As illustrated, the ESC 100 may comprise a substrate 105 with a plurality of mesas 110. The mesas 110 may be circular protrusions that extend up from the substrate 105 (i.e., out of the plane of FIG. 1A). As indicated by the uniform shading, the mesas 110 may be the same material as the substrate 105. More particularly, the mesas may be an integral part of the ESC 100. For example, a physical material removal process may be used in order to recess the top surface of the substrate 105 around the mesas 110.

As noted above, the manufacturing process that is used to form the mesas 110 on the ESC 100 is a physical material removal process. For example, masking, machining, grinding, and material blasting with abrasives are some processing operations that are executed in order to form the mesas 110. Such processes do not enable fine control of feature size or tolerances. For example, tolerances may be approximately 125 μm or greater. Additionally, extensive cleaning operations are needed in order to prepare the ESC for use in processing environments (e.g., plasma chambers, rapid thermal processing chambers, or other treatment chambers).

Referring now to FIG. 1B, a cross-sectional illustration of the ESC 100 in FIG. 1A along line B-B′ is shown. As illustrated, the mesas 110 have a uniform shape and dimension across the surface of the substrate 105. That is, mesas 110 proximate to a middle of the substrate 105 may be substantially similar to mesas 110 proximate to an edge of the substrate 105.

The shape of the mesas 110 are also limited to structures that are easy to machine with physical removal processes such as those described above. For example, the mesas 110 have rectangular shapes. That is, the top surfaces 111 are substantially flat and parallel to the flat recessed surface 106 of the substrate 105. Further, the sidewall surfaces 112 are substantially vertical. Such shapes may be detrimental to some semiconductor processing environments. For example, the sharp corners of the mesas 110 may be stress points or lead to undesirable particle generation. Accordingly, it may be desirable to have mesa shapes 110 with more rounded top surfaces 111.

Additionally, the mesas 110 have uniform widths and heights across the substrate 105. Uniform mesas 110 may be desirable for processing perfectly flat substrates. However, as layers are added to the substrate during manufacturing, the substrate may become warped due to coefficient of thermal expansion (CTE) mismatch between materials. Warped substrates may not be processed well or lead to additional stresses when uniform mesas 110 are used. Accordingly, non-uniform mesa 110 heights and/or widths may be desired in some embodiments.

Referring now to FIG. 1C, a zoomed in cross-sectional illustration of the ESC 100 is shown. The zoomed in portion includes a pair of mesas 110 and a recessed surface 106 of the substrate 105 between the mesas 110. As illustrated, the top surface 111 of the mesa 110 and the recessed surface 106 have different roughness levels. This is due to the processing of the ESC 100. For example, the top surface 111 of the mesa 110 may be polished and have a low surface roughness (shown as being substantially smooth in FIG. 1C), and the recessed surface 106 may have a greater surface roughness. The low surface roughness of the top surface 111 may have an average roughness Ra of approximately 0.03 μm or less. The high roughness of the recessed surface 106 may have an average roughness Ra of approximately 0.3 μm or more.

The difference in surface roughness between the top surface 111 of the mesas 110 and the recessed surface 106 of the substrate 105 may be the result of the physical material removal operations. For example, machining, grinding, and/or blasting with abrasives may result in a rougher surface. Meanwhile, the top surface 111 may be protected with a masking layer after a polishing process has been used to polish the substrate 105 before material removal begins. That is to say, existing physical material removal processes may result in differences between the surface roughness of different layers.

Accordingly, embodiments disclosed herein include advanced patterning processes in order to form the mesas on the substrate. In a particular embodiment, a patterning process may include the use of a laser. The laser may ablate the substrate material instead of physically removing portions of the substrate. Generally, physical removal processes require one or more solid materials (e.g., machining tool, abrasives, etc.) for directly contacting the substrate in order to remove portions of the substrate. Instead of such a physical process, electromagnetic radiation (i.e., from a laser) is used to directly remove portions of the substrate. In a particular embodiment, the laser is a pico-laser or has an even greater pulse frequency.

Such embodiments provide several advantages compared to existing solutions. One advantage is that the profile of the mesas may be controlled. Instead of being limited to flat top surfaces, the mesas may have rounded or otherwise non-flat surfaces. This can reduce stress points and minimize particle generation. A laser process may also be used in order to form non-uniform mesas. For example, the mesas may be taller proximate to a center of the substrate and shorter proximate to an edge of the substrate. Of course, the opposite configuration (i.e., shorter proximate to the center and taller proximate to the edge) can also be implemented. The use of a laser process also allows for widths of the mesas to be easily controlled.

Further, the flexibility provided by laser embodiments allow for the design of the ESC to be easily modified. Changes such as laser movement, intensity, and the like may be all that is needed to change the structure of the ESC. Such changes can easily be made by updating the programming of the laser.

In an embodiment, the speed of manufacturing ESCs may also be increased. Instead of time consuming physical removal processes (which require extensive cleaning to remove particles), a laser ablation process is used to pattern the substrate. The laser may quickly scan across the surface of the substrate in order to pattern the desired structure. Additionally, the laser ablation process does not form as many (or substantially any) particles. This eliminates the time needed for cleaning the substrate after fabrication of the mesas. Further, the laser ablation process used to form the mesas can also be used (sequentially, or at the same time) to form gas grooves into the substrate. This reduces manufacturing time as well.

Embodiments disclosed herein also maintain smooth surfaces on the patterned surfaces. For example, the top surface of the mesas may have a surface roughness that is approximately equal to the surface roughness of the recessed surfaces of the substrate. Embodiments disclosed herein may include average surface roughnesses Ra that are approximately 0.3 μm or less, or approximately 0.03 μm or less.

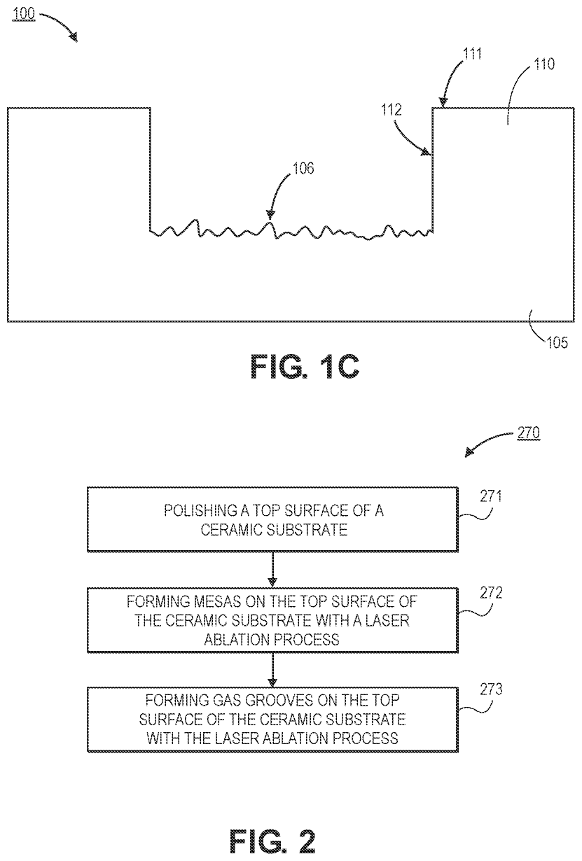

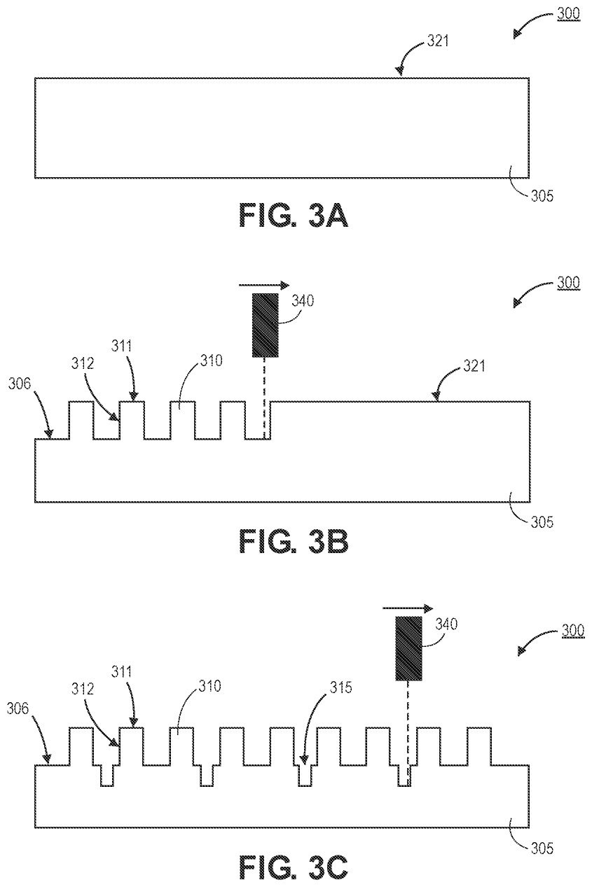

Referring now to FIG. 2, a process flow diagram of a process 270 for fabricating an ESC is shown, in accordance with an embodiment. The processes 271-273 correspond to the FIGS. 3A-3C, respectively.

In an embodiment, process 270 may begin with operation 271, which includes polishing a top surface 321 of a ceramic substrate 305. As shown in FIG. 3A, the ESC 300 includes a substrate 305. The substrate 305 may be any suitable dielectric ceramic material. For example, the substrate 305 may comprise aluminum oxide (Al₂O₃), or any other suitable dielectric ceramic material for semiconductor manufacturing purposes. The substrate 305 is shown as a solid block of material. Though, it is to be appreciated that embodiments may include a substrate 305 that includes electrodes, or other components used to enable the ESC 300. In an embodiment, the substrate 305 may be approximately 100 μm thick or thicker. For example, the substrate 305 may have a thickness that is approximately 5,000 μm or thicker in some embodiments.

In an embodiment, the top surface 321 of the substrate 305 may be polished. For example, a chemical mechanical polishing (CMP) process may be used in some embodiments. The polished top surface 321 may have an average surface roughness Ra that is approximately 5 μm or less, approximately 1 μm or less, approximately 0.3 μm or less, or approximately 0.03 μm or less.

In an embodiment, process 270 may continue with operation 272, which comprises forming mesas on the top surface of the ceramic substrate with a laser ablation process. While referred to as “laser ablation” it is to be appreciated that material “vaporization” may also be the result of the laser process. As shown in FIG. 3B, a laser 340 is scanned across the substrate 305. In the illustrated embodiment, the mesas 310 are formed in a single pass of the laser 340. Though, it is to be appreciated that two or more passes of the laser 340 may be used to form the mesas 310 in some embodiments.

The laser 340 ablates the ceramic material to form recessed surfaces 306. The recessed surfaces 306 may be provided around the mesas 310. In an embodiment, the mesas 310 may include sidewall surfaces 312 and a top surface 311. In an embodiment, the sidewall surfaces 312 may be substantially vertical (i.e., perpendicular to the recessed surfaces 306). Though, it is to be appreciated that the sidewall surfaces 312 may be sloped in some embodiments, depending on laser parameters. In an embodiment, the top surfaces 311 may be coplanar with the top surface 321. That is, the top surfaces 311 may not undergo any laser ablation. However, in other embodiments, the top surfaces 311 may be the result of some laser ablation and may be below the top surface 321.

In an embodiment, the laser 340 may be a high pulse frequency laser. In a particular embodiment, the laser 340 has a pulse length that is in the picosecond range or faster (e.g., femtosecond range). For example, the laser 340 may be referred to as being a pico-laser. In a particular embodiment a 290 fs laser 340 may be used. Any suitable wavelength laser may be used. For example, a 1030 nm laser may be used in some embodiments. The laser power may be set to up to approximately 500 W. In a particular embodiment, a laser power may be approximately 100 W. As used herein, “approximately” may refer to a range of values within ten percent of the stated value. For example, approximately 100 W may refer to a range between 90 W and 110 W. While particular ranges are provided herein, it is to be appreciated that any laser 340 configuration capable of precise photoablation may be used in accordance with embodiments disclosed herein.

The laser ablation process described herein provides significant improvements in the tolerances of the mesas 310. For example, embodiments may include dimensional tolerances that are less than 10 μm, or less than 1 μm. This is a significant improvement over devices fabricated with physical material removal, which have tolerances of 125 μm or greater. For example, the height of the mesas 310 may be approximately 20 μm or less, approximately 15um or less, or approximately 10 μm or less in some embodiments. Further, while all mesas 310 are shown as having the same height in FIG. 3B, it is to be appreciated that embodiments may include mesas 310 with variable heights, as will be described in greater detail below.

In an embodiment, the process 270 may continue with operation 273, which comprises forming gas grooves on the top surface of the ceramic substrate with the laser ablation process. As shown in FIG. 3C, the laser 340 may be scanned across the substrate in order to form gas grooves 315 between mesas 310. In the illustrated embodiment, the mesas 310 are completed first, and then the gas grooves 315 are formed into the recessed surfaces 306. Though, in other embodiments, the gas grooves 315 may be formed at the same time the mesas 310 are formed. In an embodiment, the same laser 340 may be used for both the formation of the mesas 310 and the gas grooves 315. In other embodiments, different lasers 340 or the same laser with different laser settings may be used to form the mesas 310 and the gas grooves 315.

In an embodiment, the gas grooves 315 may have a depth that is approximately 10 μm or less. Though, deeper gas grooves 315 may also be used in some embodiments. In the illustrated embodiment, the gas grooves 315 have substantially flat bottom surfaces and vertical sidewalls. Though other configurations may be used, as will be described in greater detail below.

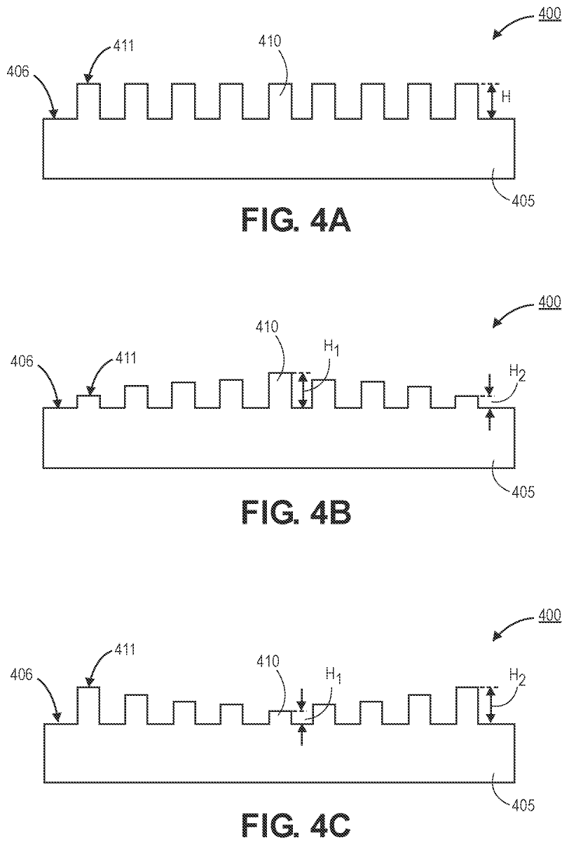

Referring now to FIGS. 4A-4C a series of ESCs 400 are shown, in accordance with various embodiments. Each of the ESCs 400 shown in FIGS. 4A-4C may be formed using processes such as process 270 described in greater detail above. Further, while shown without gas grooves, it is to be appreciated that gas grooves may be fabricated into the substrates 405 similar to what is shown in FIG. 3C.

Referring now to FIG. 4A, a cross-sectional illustration of an ESC 400 is shown, in accordance with an embodiment. In an embodiment, the ESC 400 comprises a substrate 405. The substrate 405 may be a dielectric ceramic substrate. For example, the substrate 405 may comprise aluminum and oxygen (e.g., aluminum oxide (Al₂O₃)). In an embodiment, a plurality of mesas 410 may extend up from a recessed surface 406 of the substrate 405. The mesas 410 may have substantially similar shapes and dimensions across the substrate 405. For example, all of the mesas 410 may have a height H. The height H may be approximately 20 μm or less, approximately 15 μm or less, or approximately 5 μm or less.

In an embodiment, the mesas 410 may have top surfaces 411 that are substantially flat. That is, the top surfaces 411 may be substantially parallel to the recessed surface 406. The top surfaces 411 may be connected to the recessed surface 406 by substantially vertical sidewalls in some embodiments. The shape of the mesas 410 may be generally considered as being rectangular (as viewed in a cross-section). When viewed from above, the mesas 410 may be circular (to provide a cylindrical shape to the mesas 410). However, the laser ablation process is flexible, and the mesas 410 may have any three dimensional shape. As used herein, the “shape” of a mesa 410 may be a reference to either the three-dimensional shape of the mesa 410 or a cross-sectional shape of the mesa 410.

Referring now to FIG. 4B, a cross-sectional illustration of an ESC 400 is shown, in accordance with an additional embodiment. As shown, the ESC 400 comprises a substrate 405 with a recessed surface 406. In an embodiment, the plurality of mesas may have non-uniform dimensions across the substrate 405. For example, a mesa 410 proximate to a center of the substrate 405 may have a first height H1 and a second mesa 410 proximate to an edge of the substrate 405 may have a second height H2. In an embodiment, the first height H1 may be greater than the second height H2. Additionally, the mesas between the center and the edge may have decreasing heights from H1 to H2. Such an embodiment may be beneficial when the wafer that is being processed on the ESC 400 has an existing warpage.

Referring now to FIG. 4C, a cross-sectional illustration of an ESC 400 is shown, in accordance with yet another embodiment. In an embodiment, the ESC 400 in FIG. 4C is similar to the ESC 400 in FIG. 4B, with the exception of the heights being inversed. That is, the first height H1 proximate to the center of the substrate 405 may be less than the second height H2 proximate to the edge of the substrate 405. Similarly, the mesas 410 between the center and the edge may increase in height as their position moves outward. Such an embodiment may be suitable for processing a wafer that has a warpage that is opposite in direction that the warpage suitable for the embodiment shown in FIG. 4B.

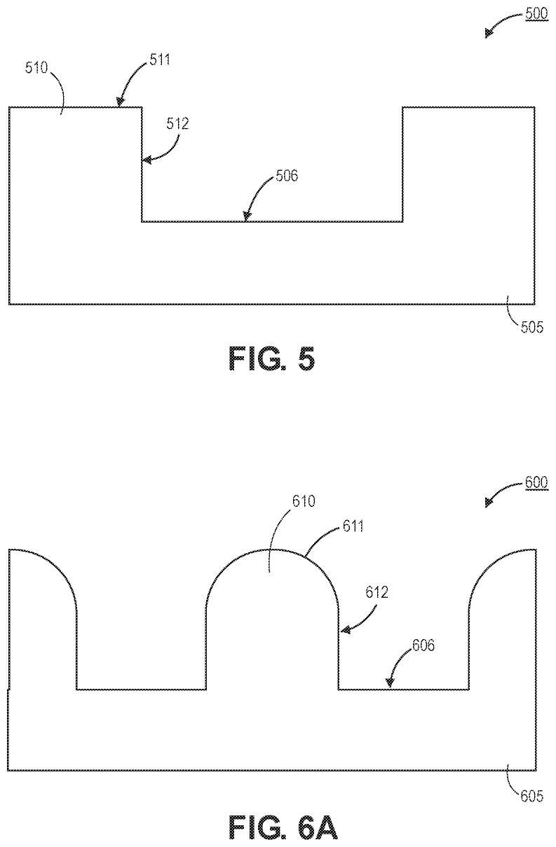

Referring now to FIG. 5, a zoomed in cross-sectional illustration of an ESC 500 is shown, in accordance with an embodiment. The ESC 500 may include a substrate 505. Mesas 510 may extend up from a recessed surface 506. Top surfaces 511 of the mesas 510 may be connected to the recessed surface 506 by the sidewalls 512. As noted above the laser ablation process results in a substantially smooth surface. Even when the top surface 511 is a polished surface, the recessed surface 506 may maintain a similar surface roughness. That is, a surface roughness of the top surface 511 may be substantially equal to a surface roughness of the recessed surface 506. As used herein, “substantially equal” may refer to two values that are within ten percent of each other. In a particular embodiment, average surface roughnesses Ra of the top surface 511 and the recessed surface 506 may be approximately 5 μm or less, approximately 1 μm or less, approximately 0.3 μm or less, or approximately 0.03 μm or less. It is to be appreciated that this uniformity in surface roughness is different than existing ESCs that use physical patterning processes, which leave a recessed surface that is significantly rougher than the top surface of the mesas.

Additionally, while shown as having substantially equal surface roughnesses, the average surface roughness Ra of the top surface 511 may be different than the average surface roughness Ra of the recessed surface 506. In an embodiment, both surfaces 511 and 506 may be smoother than what is provided with a typical mechanical removal process (e.g., a surface roughness of approximately 1 μm or less, approximately 0.3 μm or less, or approximately 0.03 μm or less) but still different from each other. As an example, surface 511 may have a surface roughness of approximately 0.03 μm or less and surface 506 may have a surface roughness of approximately 0.3 μm or less. While an example with the top surface 511 being smoother than the recessed surface 506 is provided, embodiments are not limited to such configurations. In other embodiments, the recessed surface 506 may be smoother than the top surface 511.

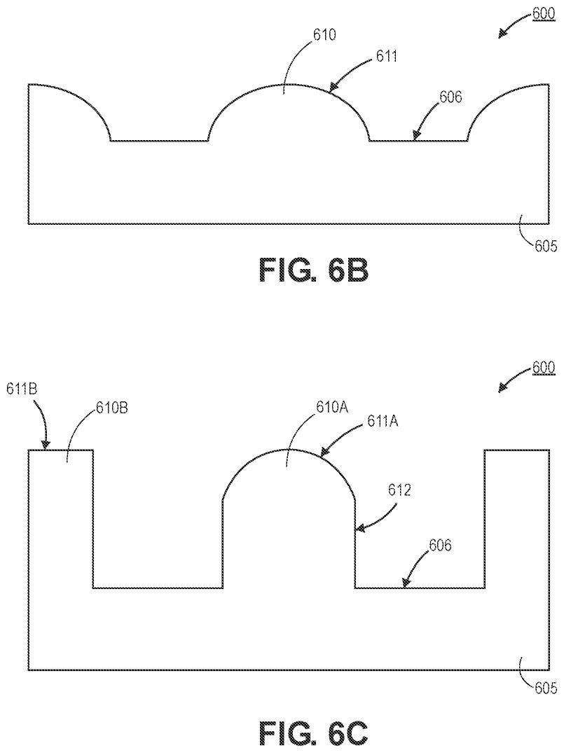

Referring now to FIGS. 6A-6E, a series of cross-sectional illustrations depicting ESCs 600 with different mesa topographies is shown, in accordance with various embodiments. The different mesa topographies are enabled by the use of the laser ablation process. For example, different laser settings can be used in order to modify the shape of the mesas, and/or allow for different shaped mesas within a single ESC 600.

Referring now to FIG. 6A, a cross-sectional illustration of an ESC 600 is shown, in accordance with an embodiment. The ESC 600 may comprise a substrate 605 with a recessed surface 606. Mesas 610 may extend up from the recessed surface 606. As shown in FIG. 6A, the mesas 610 may have non-flat top surfaces 611. The top surfaces 611 may be referred to as being rounded or domed. In an embodiment, the top surfaces 611 may be connected to the recessed surface 606 by sidewalls 612, such as vertical sidewalls 612. More particularly, the domed top surfaces 611 may be raised up from the recessed surface 606.

Referring now to FIG. 6B, a cross-sectional illustration of an ESC 600 is shown, in accordance with another embodiment. In the embodiment shown in FIG. 6B, the top surfaces 611 are directly connected to the recessed surface 606. That is, the mesas 610 may be referred to as not having any sidewalls. Instead, the domed top surface 611 lays directly on the recessed surface 606.

Referring now to FIG. 6C, a cross-sectional illustration of an ESC 600 is shown, in accordance with another embodiment. In the embodiment shown in FIG. 6C, the mesas 610 have non-uniform shapes. For example, first mesa 610A has a domed or curved top surface 611A, and second mesa 610B has a flat top surface 611B. While two examples of different mesa 610 shapes are shown in FIG. 6C, it is to be appreciated that any number of different mesa 610 shapes may be formed using laser ablation processes such as those described in greater detail herein.

Referring now to FIG. 6D, a cross-sectional illustration of an ESC 600 is shown, in accordance with another embodiment. In the embodiment shown in FIG. 6D, the ESC 600 further comprises a gas groove 615 that is formed between the mesas 610. The gas groove 615 may include a flat bottom surface 616. The bottom surface 616 may be parallel to the recessed surface 606. Additionally, the gas groove 615 may have substantially vertical sidewalls 617.

Referring now to FIG. 6E, a cross-sectional illustration of an ESC 600 is shown, in accordance with yet another embodiment. As shown in FIG. 6E, the corners of the structure are rounded. For example, corner 613 (where the top surface 611 and the sidewall surface 612 meet) and corner 618 (where the recessed surface 606 and the bottom surface 616 meet) may be rounded. Additionally, the bottom surface 616 of the gas groove 615 may be rounded as well. Providing rounded corners may be desirable in order to mitigate high stress concentrations and/or to mitigate particle generation. Such curved surfaces are not easily machinable using standard physical machining processes.

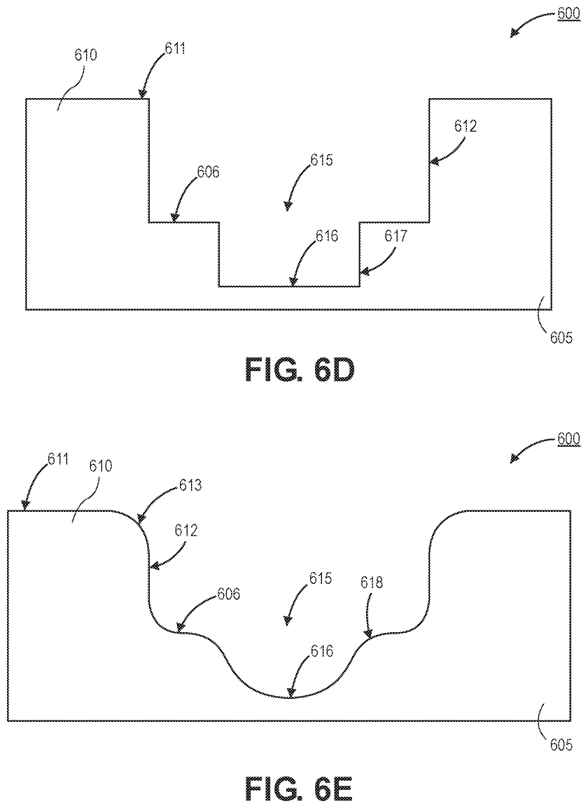

Referring now to FIG. 7, a plan view illustration of an ESC 700 is shown, in accordance with an embodiment. In an embodiment, the ESC 700 may include a substrate 705 with a plurality of mesas 710 that extend up from the substrate 705. While a certain configuration of mesas 710 is shown as an example, it is to be appreciated that the ESC 700 may include any number of mesas 710, including hundreds or more mesas 710. In an embodiment, the mesas 710 may have uniform shapes and dimensions. In other embodiments, non-uniform shapes or dimensions may be used, similar to any of the embodiments described in greater detail herein.

In an embodiment, the ESC 700 may also include gas grooves 715. The gas grooves 715 may be used to distribute gasses across the backside of the wafer or substrate that is being processed. In an embodiment, the gas grooves 715 may be fabricated along (e.g., at the same time, or sequentially) with the mesas 710 using a laser ablation process, such as the processes described in greater detail herein. The location and number of the gas grooves 715 is exemplary, and it is to be appreciated that any gas groove 715 configuration may be used.

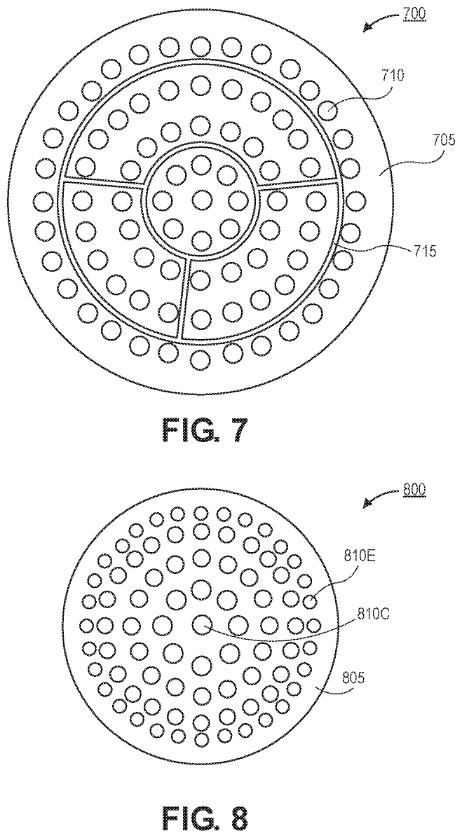

Referring now to FIG. 8, a plan view illustration of an ESC 800 is shown, in accordance with an additional embodiment. Particularly, the ESC 800 has mesas 810 of non-uniform dimensions. For example, mesas 810C proximate to a center of the substrate 805 have a first diameter and the mesas 810E proximate to an edge of the substrate 805 have a different second diameter. In the embodiment shown in FIG. 8, the first diameter is greater than the second diameter. Though, in other embodiments, the first diameter may be smaller than the second diameter. Additionally, the spacing between mesas 810 may be non-uniform in some embodiments. Further the mesas 810 may have non-uniform heights similar to other embodiments described in greater detail herein.

Radial non-uniformities can also be applied to other parameters of the ESC. For example, surface roughness can be modulated across the surface of the ESC. In such an embodiment, zones of the ESC at different radial locations may have different surface roughnesses. In one embodiment, mesas of the ESC (in a first zone towards the center of the ESC) may have a first surface roughness. Additionally, a backside gas seal band (in a second zone towards the edge of the ESC) may have a second surface roughness that is less than the first surface roughness. Such an embodiment may result in an improved seal for the backside gasses during processing, while also improving dechucking performance. The rougher mesa surface may be less sensitive to residual charges. Variable surface roughnesses may be enabled by modifying the laser parameters used to form the various features.

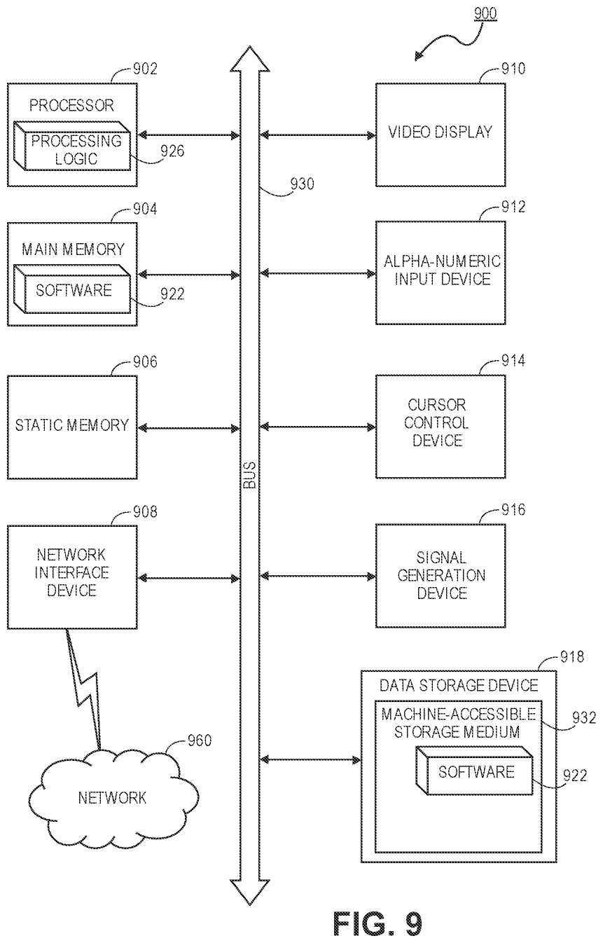

Referring now to FIG. 9, a block diagram of an exemplary computer system 900 of a processing tool is illustrated in accordance with an embodiment. In an embodiment, computer system 900 is coupled to and controls processing in the processing tool. Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 932 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 960 via the system network interface device 908. In an embodiment, the network interface device 908 may operate using RF coupling, optical coupling, acoustic coupling, or inductive coupling.

While the machine-accessible storage medium 932 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An electrostatic chuck (ESC), comprising:
a substrate with a first surface, wherein the first surface has a first surface roughness; and
a plurality of mesas extending up from the first surface, wherein the plurality of mesas each include a second surface, wherein the second surface has a second surface roughness, wherein the first surface roughness and the second surface roughness both have an average surface roughness Ra of approximately 0.3 μm or lower.

2. The ESC of claim 1, wherein the plurality of mesas have a non-uniform height.

3. The ESC of claim 2, wherein a first mesa towards a center of the substrate has a first height, and wherein a second mesa towards an edge of the substrate has a second height that is different than the first height.

4. The ESC of claim 3, wherein the first height is greater than the second height.

5. The ESC of claim 3, wherein the first height is less than the second height.

6. The ESC of claim 1, wherein the second surface is domed.

7. The ESC of claim 6, wherein the second surface is coupled to the first surface by substantially vertical sidewalls.

8. The ESC of claim 1, further comprising a gas groove into the first surface of the substrate.

9. The ESC of claim 1, wherein a height of each of the plurality of mesas is up to approximately 15 μm.

10. The ESC of claim 1, wherein the first surface roughness is substantially equal to the second surface roughness.

11. The ESC of claim 1, wherein the first surface roughness is different than the second surface roughness.

12. The ESC of claim 1, further comprising:
a seal band towards a perimeter of the of the substrate, wherein the seal band has a third surface roughness, wherein the third surface roughness is smoother than the second surface roughness.

13. An electrostatic chuck (ESC), comprising:
a substrate with a center and an edge;
a first mesa proximate the center of the substrate, wherein the first mesa has a first shape and a first height; and
a second mesa proximate the edge of the substrate, wherein the second mesa has a second shape and a second height, and wherein the first shape is different than the second shape and/or the first height is different than the second height.

14. The ESC of claim 13, wherein the first height is larger than the second height.

15. The ESC of claim 13, wherein the first shape has a rectangular cross-section, and wherein the second shape has a domed cross-section.

16. The ESC of claim 13, wherein a domed surface of the second shape is connected to the substrate by substantially vertical sidewalls.

17. The ESC of claim 13, wherein the substrate has a first surface roughness, and wherein top surfaces of the first mesa and the second mesa have a second surface roughness, and wherein the first surface roughness is substantially equal to the second surface roughness.

18. The ESC of claim 17, wherein the first surface roughness and the second surface roughness have an average roughness Ra that is approximately 1 μm or less.

19. A method of forming an electrostatic chuck (ESC), comprising:
polishing a first surface of a substrate;
forming a plurality of mesas into the first surface of the substrate with a laser ablation process; and
forming a gas groove into the substrate between mesas.

20. The method of claim 19, wherein the laser ablation process is done with a picosecond pulse frequency laser or greater.
